(19) United States
(12) Patent Application Publication
(10) Pub. No.: US 2008/0122453 A1
(43) Pub. Date: May 29, 2008

(54) Low Noise Radiation Sensor

(75) Inventor: Scott R. Hunter, Oak Ridge, TN (US)

Correspondence Address: DEMONT & BREYER, LLC, 100 COMMONS WAY, Ste. 250, HOLMDEL, NJ, 07733, US

(73) Assignee: Multispectral Imaging, Inc., Parsippany, NJ (US)

(21) Appl. No.: 11/736,274

(22) Filed: Apr. 17, 2007

Related U.S. Application Data
(60) Provisional application No. 60/792,506, filed on Apr. 17, 2006.

(51) Int. Cl. G01R 27/26

(52) U.S. Cl. 324/661; 324/658

(57) ABSTRACT

A radiation sensor array that exhibits improved performance is disclosed. The radiation sensor array dissipates kinetic energy within a capacitive sensing element and establishes an electric field across a two capacitor bridge circuit that comprises the capacitive sensing element, wherein the electric field has substantially constant magnitude during both sensing and reset modes of operation. The electric field, however, has opposite polarity during the sense and reset modes.

### CROSS REFERENCE TO RELATED APPLICATIONS

This application claims the benefit of U.S. Provisional Patent Application Ser. No. 60/792,506, filed 17 Apr. 2006, which is incorporated herein by reference.

The underlying concepts, but not necessarily the language, of the following cases are incorporated by reference:
U.S. patent application Ser. No. 11/279,954, filed 17 Apr. 2006;
U.S. patent application Ser. No. 11/688,745, filed 20 Mar. 2007; and
U.S. patent application Ser. No. 11/688,752, filed 20 Mar. 2007.

If there are any contradictions or inconsistencies in language between this application and one or more of the cases that have been incorporated by reference that might affect the interpretation of the claims in this case, the claims in this case should be interpreted to be consistent with the language in this case.

### FIELD OF THE INVENTION

The present invention relates to capacitive sensors in general, and, more particularly, to MEMS capacitive sensors.

### BACKGROUND OF THE INVENTION

Capacitive sensors respond to an environmental stimulus with a change in the capacitance value of a sensor element. Such sensors are used in a wide array of applications, such as in accelerometers, gyroscopes, thermometers, pressure sensors, and radiation detectors. Capacitive sensors enjoy such popularity because they are able to provide high measurement sensitivity at low cost.

The advent of Micro Electro Mechanical Systems (MEMS) technology has resulted in the development of capacitive sensors that are easily integrated with electrical circuitry, which offers even lower cost and improved performance. A MEMS capacitive sensor comprises a pair of capacitor plates, one of which is typically mechanically-coupled to a mechanically-active element that responds to the environmental stimulus to be sensed. As this mechanically-active element responds to the environmental stimulus, the spacing between the two capacitor plates is changed. As a result, the capacitance of the capacitive sensor is changed.

Typically, the capacitance of the capacitive sensor element is read during a “sense mode” by applying a sense voltage across a two capacitor bridge circuit that comprises the capacitive sensor (i.e., a sense capacitor) and a reference capacitor. This sense voltage induces an electric field across each capacitor. In response to this electric field, electric charge is stored in each capacitor. The amount of charge stored in each capacitor is a function of the capacitance of that particular capacitor. The ratio of charge stored by each capacitor determines the fraction of the sense voltage that appears on the common node between the two capacitors. Periodically, the capacitor bridge circuit is put into a “reset mode” by removing the sense voltage across the two capacitor bridge circuit. In this reset mode the stored charge (and hence, the voltage at the common node) is reset to a nominal value in preparation for a new “sense mode” measurement.

Prior-art capacitor sensing systems and methods have several disadvantages, however. The most notable disadvantage arises from a high level of noise introduced into the output of the sensing system by the techniques used to read the charge stored on the sense capacitor. Capacitive sensing elements themselves exhibit little, if any, Johnson noise or 1/f noise, since these noise sources arise from thermodynamics within a resistive element. Once a capacitive sensing element is included in a readout circuit, however, Johnson noise and 1/f noise in the transistors and/or other circuit elements can dominate the total noise floor of the system due to the low transducer sensitivity and low sense capacitance. Thermo-mechanical noise in the sensing system arises from Brownian noise caused by the random motion of particles and components in the sensor, particularly for vacuum-packaged devices. Mechanical noise arises from mechanical response of the sensor element to a variety of mechanical energy inputs, such as vibration, shock, and electrostatic forces that develop during the operation of the sensor system. In addition, when a capacitive sensing element is used to sense incident electromagnetic radiation, such as infrared radiation, the statistical nature of the radiation flux can add to the thermomechanical noise floor of the sensing system.

A capacitive sensor system with better noise performance than prior-art capacitor sensors is desirable.

### SUMMARY OF THE INVENTION

The present invention provides a means of reading the capacitance of a capacitive sensing element without some of the disadvantages of the prior art. The present invention is suitable for use with any capacitive sensing element; however, the present invention is particularly suitable for use with those capacitive sensing elements that employ a mechanically-active capacitor plate that moves in response to an environmental stimulus.

In the prior art, when the capacitive sensor is alternated between sense and reset modes, the application and removal of the sense voltage leads to a change in the electric field that is developed across the plates of the capacitive sensing element. When the electric field is present, it gives rise to an electrostatic force that acts to attract the capacitor plates of the capacitive sensing element toward each other. When the electric field is removed, the electrostatic attraction between the plates goes away and the plates separate. As a result, a voltage signal is developed on the output of the capacitive sensor. This voltage signal is referred to as “mechanical noise” and reduces the performance of the capacitive sensor. Often, the mechanically-active capacitor plate will physically oscillate (i.e., “ring”) at its mechanical resonant frequency upon the removal of the electric field. This ringing imparts a sinusoidal noise signal on the sensor's output.

In contrast to the prior art, embodiments in accordance with the present invention reduce or eliminate mechanical noise from the capacitive sensor's output. Some embodiments provide an electric field across the plates of a capacitive sensing element that remains substantially constant for both sense mode and reset mode. As a result, no significant change in electrostatic attraction between the capacitor plates arises when switching between the sense and reset modes. Some embodiments provide an electrical high-pass filter, which dissipates kinetic energy in the sensing element through resistive heating, thereby reducing the effect of mechanical noise.

As in the prior art, a capacitive sensing element (i.e., a sense capacitor) is electrically-connected to a reference capacitor to form a two capacitor bridge circuit. During the sense mode, symmetric fast rise-time pulsed voltages that have equal magnitude but opposite sign are applied to the voltage inputs of the capacitor bridge. During the reset mode, the voltages applied to the voltage inputs of the two capacitor bridge circuit are reversed. As a result, the polarity of the electric field induced across the capacitive sensing element is reversed; however, the magnitude of the electric field remains substantially constant. Since the magnitude of the electrostatic attraction between the capacitor plates of the capacitive sensing element is a function of only the magnitude of the applied electric field, it too remains substantially constant. Thus, embodiments of the present invention avoid or mitigate the mechanical response of the sensing element due to a change in sensing voltage. Little or no mechanical noise is generated, therefore, when rapidly switching between sense and reset modes (i.e., when the voltage switches at a rate faster than the mechanical response of sensor 202).

Kinetic energy can be imparted to the mechanically-active sensor element by environmental stimuli, such as shock and/or vibration, or by electrical excitation, such as at turn-on when the sense voltage is applied. In some embodiments of the present invention, a high-pass electrical filter is employed to dissipate kinetic energy in a capacitive sensing element. In these embodiments, mechanical energy is damped by converting it into an electrical current at the common node of the two capacitor bridge circuit. This electrical current is then dissipated as resistive heating in a resistor that forms part of the high-pass filter. Since the frequency of this electrical current is at or near the mechanical resonant frequency of the sensing element, it is typically much higher in frequency than most environmental stimuli to be sensed. The high-pass filter is formed with a cut-off frequency that is between the frequency spectrum of the environmental stimulus being sensed and the mechanical resonance of the sensing element. As a result, electrical current due to kinetic energy in the sensor element is passed into the high-pass filter and dissipated.

The illustrative embodiment of the present invention comprises a circuit comprising: (1) a two capacitor bridge circuit comprising a sense capacitor having a first terminal and a second terminal, wherein the capacitance of the sense capacitor is a function of an environmental stimulus, and a reference capacitor having a first terminal and a second terminal, wherein the second terminal of the reference capacitor and the second terminal of the sense capacitor are electrically-connected; (2) a first input for providing a first voltage signal, wherein the first input and the first terminal of the sense capacitor are electrically-connected; and (3) a second input for providing a second voltage signal, wherein the second input and the first terminal of the reference capacitor are electrically-connected; wherein the first voltage signal and the second voltage signal produce a first electric field across the two capacitor bridge circuit during a sense mode and a second electric field across the two capacitor bridge circuit during a reset mode, and wherein the first electric field and the second electric field have substantially equal magnitude and opposite polarity.

### BRIEF DESCRIPTION OF THE DRAWINGS

FIG. 1 depicts the salient elements of an infrared camera in accordance with an illustrative embodiment of the present invention.

FIG. 2 depicts a plan view of a portion of a sensor array, in accordance with the illustrative embodiment of the present invention.

FIG. 3A depicts a cross-sectional view of sensor 202, before absorption of incident electromagnetic radiation, in accordance with the illustrative embodiment of the present invention.

FIG. 3B depicts a cross-sectional view of sensor 202, after absorption of incident electromagnetic radiation, in accordance with the illustrative embodiment of the present invention.

FIG. 4 depicts a schematic diagram of details of a portion of circuit for reading the output of a capacitive sensor, in accordance with the illustrative embodiment of the present invention.

FIG. 5 depicts a timing diagram of signal levels within circuit 400.

FIG. 6 depicts a method for operating circuit 400.

FIG. 7 depicts a method for dissipating kinetic energy in sensor 202.

### DETAILED DESCRIPTION

The following terms are defined for use in this Specification, including the appended claims:
Mechanically-coupled means that two or more objects interact with one another such that movement of one of the objects affects the other object. For example, consider an actuator and a platform. When triggered, the actuator causes the platform to move. The actuator and the platform are therefore considered to be “mechanically-coupled.” Mechanically-coupled devices can be, but are not necessarily, physically coupled. In particular, two devices that interact with each other through an intermediate medium are considered to be mechanically coupled. Continuing with the example of the platform and the actuator, if the platform supports a load such that the load moves when the platform moves (due to the actuator), then the actuator and the load are considered to be mechanically coupled as well.
Electrically-coupled means that two objects are in electrical contact. This can be via direct physical contact (e.g., a plug in an electrical outlet, etc.), via an electrically-conductive intermediate (e.g., a wire or conductive trace that connects devices, etc.), or via intermediate devices, etc. (e.g., a resistor, capacitor, etc.).
Electrically-connected means that two objects are in direct electrical contact without any intervening elements. In other words, the point of contact between the two objects remains at substantially the same voltage for substantially any current (neglecting any voltage drop due to the resistivity of the physical connection medium, such as a wire).
Monolithically-integrated means formed either: in the body of a substrate, typically by etching into the substrate or; on the surface of the substrate, typically by patterning layers disposed on the surface.
Thermal Bimorph means a structure (e.g., beam, etc.) that exhibits thermal bimorph behavior (i.e., thermally-induced bending response). Thermal bimorph behavior can be created in single-layer (single material) structures, bi-layer (bi-material) structures, or in structures that have more than two layers comprising two or more materials. In other words, notwithstanding the prefix “bi,” a thermal bimorph can have more or less than two discrete layers comprising more or less than two different materials.
Corrugations means a series of alternating ridges and trenches, wherein one ridge and one trench collectively define a “corrugation.”
Mechanical resonance period means the inverse of a mechanical resonant frequency. In other words, a mechanical resonance period of a mechanical element, Tᵣₑₛ is equal to the inverse of an associated mechanical resonant frequency of the mechanical element, 1/ωᵣₑₛ (i.e., Tᵣₑₛ=1/ωᵣₑₛ).

### Other terms will be defined, as appropriate, throughout this specification.

FIG. 1 depicts the salient elements of an infrared camera in accordance with an illustrative embodiment of the present invention. Infrared camera 100 comprises infrared imaging optics 102, shutter 104, integrated focal plane array 110, temperature controller 112, and camera electronics 114, interrelated as shown.

Infrared imaging optics 102 includes one or more lenses that receive radiant energy, such as infrared radiation. Infrared radiation that is received by infrared imaging optics 102 is directed toward shutter 104. The shutter controls the amount of radiation that is directed toward integrated focal plane array 110. Those of ordinary skill in the art will know how to make, specify, and use infrared imaging optics 102 and shutter 104.

Integrated focal plane array 110 comprises sensor array 106 and read-out integrated circuit (“ROIC”) 108. Although in the illustrative embodiment sensor array 106 is monolithically-integrated with ROIC 108, it will be clear to those skilled in the art how to make and use alternative embodiments of the present invention wherein sensor array 106 is packaged with ROIC 108 using another appropriate technology such as:
i. hybrid integration technology; or
ii. multi-chip module integration technology; or
iii. conventional integrated circuit packaging; or
iv. any combination of i, ii, and iii.

Sensor array 106 receives the radiant energy that is captured by infrared imaging optics 102 and admitted by shutter 104. Sensor array 106 is located at the focal point of infrared imaging optics 102 and is, therefore, properly termed a “focal plane array.” As described later in this specification, sensor array 106 comprises an array of micromechanical capacitive sensors that respond to infrared radiation. These sensors have support arms that incorporate two thermal bimorphs and a thermal isolator, in accordance with the illustrative embodiment of the present invention.

In response to the received radiation, the capacitance of the various sensors of sensor array 106 changes. These capacitances are “read” or “extracted” by ROIC 108, in known fashion. ROIC 108 generates voltage signals that are indicative of the extracted capacitances. ROIC 108 performs various other functions as well, including signal conditioning and amplification. Those skilled in the art will know how to use ROIC 108 to extract the capacitance of the various sensors in sensor array 106 and provide a voltage signal indicative thereof.

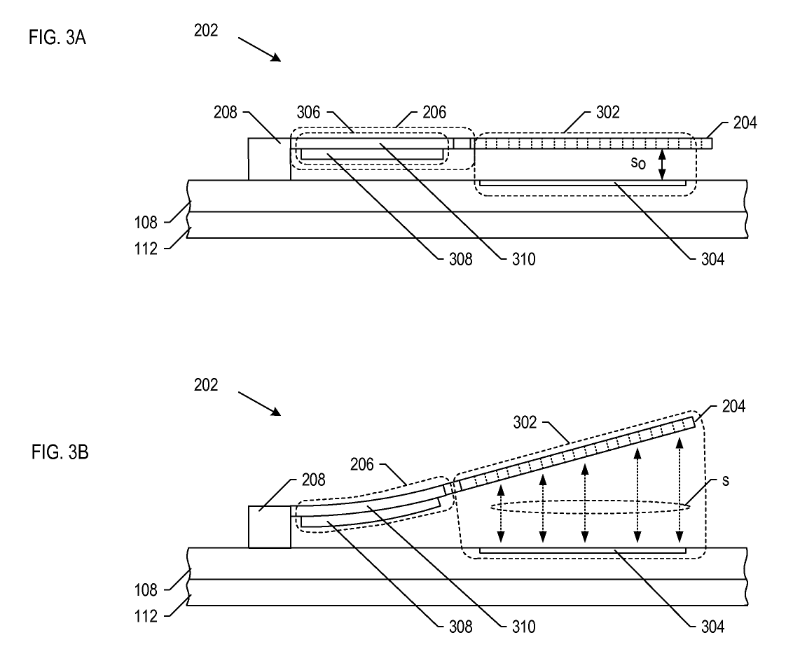

Temperature controller 112 provides integrated focal plane array 110 with thermal isolation from its environment, other than from the received infrared radiation. Temperature controller 112 also proactively controls the temperature of integrated focal plane array 110, as described in more detail below and with respect to FIG. 3. Camera electronics 114 includes various amplification, offset, and gain-control electronics, multiplexing and analog-to-digital circuitry, a camera-control microprocessor, various external control electronics, digital read-out and the like. Concisely, camera electronics 114 receives the voltage signals from ROIC 108 and processes the signals into an image. Camera electronics 114 also control the focus of infrared imaging optics 102 and control shutter 104 and temperature stabilizer 112. Those skilled in the art will be familiar with the design and use of the various devices and circuits that compose camera electronics 114 and know how to integrate sensor array 106 therewith.

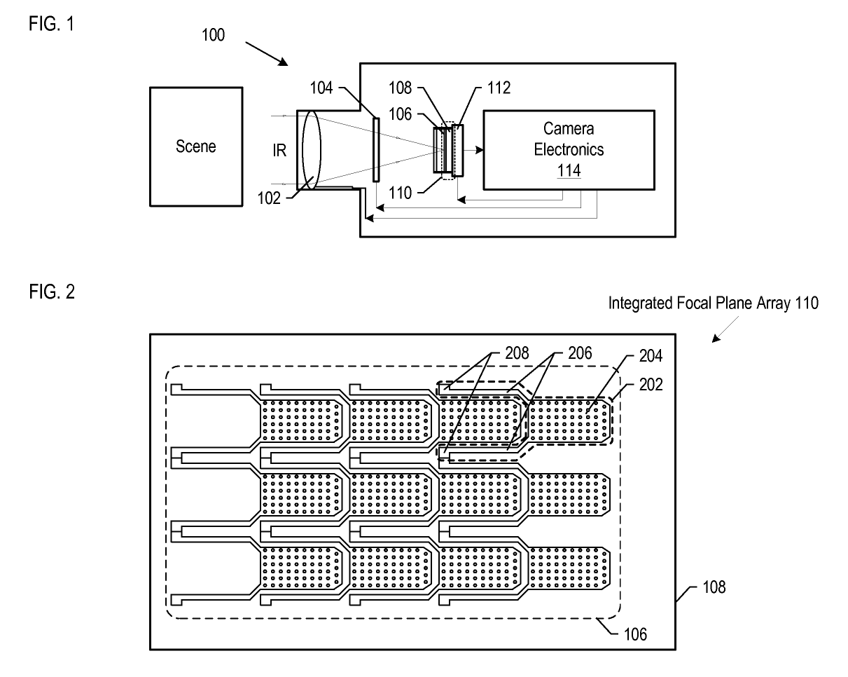

FIG. 2 depicts a plan view of a portion of a sensor array, in accordance with the illustrative embodiment of the present invention. Sensor array 106 comprises a plurality of closely-spaced capacitance sensors 202, each of which defines a “pixel” of the array. Only a few (twelve) sensors 202 are depicted in array 106. Each of sensors 202, which are substantially identical, comprises a plate 204, support arms 206, and anchors 208. As described below and with reference to FIG. 3, plate 204 is suspended above an electrode (not shown in FIG. 2) of ROIC 108 to form a capacitor whose capacitance is a function of the spacing between them. Sensors 202, and their operation, are described in detail in U.S. patent application Ser. Nos. 11/279,954, 11/688,745, and 11/688,752, which are incorporated herein by reference.

FIGS. 3A and 3B depict a cross-sectional view of sensor 202, before and after absorption of incident electromagnetic radiation (respectively), in accordance with the illustrative embodiment of the present invention.

Plate 204 and substrate electrode 304 together form sense capacitor 302. Plate 204 functions as a radiant-energy absorber and the spacing, s, between plate 204 and substrate electrode 304 forms a resonant cavity that enhances the absorption of radiation in the range of interest. Radiation absorbed by plate 204 is converted into heat, which is conducted to support arms 206. A resonant cavity for radiation within the range of visible light through long wave infrared radiation can be established with proper selection of the quiescent-state spacing, sₒ, between plate 204 and substrate electrode 304.

Infrared radiation is also absorbed by the materials that compose plate 204. Plate 204 comprises an overlying layer of at least one layer of electrically-conductive material and at least one underlying layer of dielectric material. Suitable materials for inclusion in the overlying layer include, without limitation, titanium, titanium-tungsten, titanium-nitride-tungsten, titanium-nitride, chrome, and nichrome. Suitable materials for inclusion in the underlying layer of dielectric material include, without limitation, silicon dioxide, silicon nitride, and silicon oxynitride.

In some embodiments, the overlying layer of at least one layer of electrically-conductive material comprises a titanium nitride layer that serves as an impedance matching layer to match the free space impedance of the resonant cavity. The titanium nitride layer also imparts electrical conductivity, which is required for plate 204 to serve as a movable electrode in sense capacitor 302.

The electrically-conductive material and underlying dielectric materials are chosen to provide a plate 204 that is a free-space impedance match for the electromagnetic radiation of interest. In some embodiments, this impedance match is approximately 377 ohms.

Support arms 206 support plate 204 above ROIC 108, and also provide electrical conductivity between plate 204 and ROIC 108. Each of support arms 206 comprises thermal bimorph 306 and a highly thermally conductive layer (not shown), which provides a low thermal resistance path between thermal bimorph 306 and plate 204. As a result, the conduction of heat from plate 204 into support arms 206 affects the spacing, s, between plate 204 and its underlying electrode. The capacitance of sensor 202, therefore, is a function of the intensity of electromagnetic radiation incident upon plate 204.

Thermal bimorphs 306 each comprise lower bimorph element 308 and upper bimorph element 310 (i.e., a portion of the structural material of support arm 206). In some embodiments, thermal bimorphs 306 each comprises lower bimorph element 308, which has a relatively higher thermal expansion coefficient (TEC), disposed below upper bimorph element 310, which has a relatively lower TEC. In some embodiments, the thermal bimorphs comprise a metal, such as aluminum or gold, disposed beneath a dielectric layer(s), such as silicon dioxide and/or silicon oxynitride and/or silicon nitride and/or hydrogenated amorphous silicon carbide.

Since the metal layer, which has the relatively higher TEC, is located beneath the dielectric layer, which has the relatively lower TEC, thermal bimorphs 306 will bend “upwards” (i.e., away from ROIC 108) in response to increasing temperature. Upward bending is advantageous because it improves dynamic range, since greater range of movement is permitted. Also, upward movement decreases the likelihood of inadvertent contact with the substrate, which is likely to result in stiction (i.e., permanent attachment of the movable element to the substrate). Of course, the material layers can be inverted (i.e., layer with the lower TEC beneath the layer with the higher TEC) to provide downward bending upon heating, if desired.

Although the illustrative embodiment comprises a sensor wherein plate 204 is parallel to the substrate (i.e., ROIC 108) when the plate is in its quiescent state, it will be clear to those skilled in the art, after reading this specification, how to make and use alternative embodiments of the present invention wherein plate 204 is in a non-parallel relationship with the substrate when plate 204 is in its quiescent state. It will be apparent to those skilled in the art that in these alternative embodiments, thermal tuning can be used to control the separation distance and/or angle between plate 204 and ROIC 108.

Anchors 208 provide an anchor point for support arms 206. In addition, anchors 208 provide an electrical via to ROIC 108. Anchors 208 are in intimate contact with ROIC 108 and anchors 208 provide both mechanical contact and electrical contact between support arms 206 and ROIC 108. In some embodiments, a thermal isolator is included between anchor 208 and thermal bimorph 306. This thermal isolator retards the flow of heat from the thermal bimorph into the substrate, thereby improving the responsivity of sensor 202 to incident radiation.

Sensor array 106 would typically be implemented as a much larger array, such as a 160×120 pixel array, which includes 19,200 sensors 202. Since individual sensors 202 are micron-sized, the array is formed on ROIC 108 via standard micromachining techniques. In some alternative embodiments (not depicted), the array is a linear array wherein sensors 202 are linearly arranged. Although the illustrative embodiment comprises a sensor array that is formed on an ROIC, it will be clear to those skilled in the art, after reading this specification, how to make and use alternative embodiments of the present invention wherein sensor array is formed on a substrate that is not an ROIC. Suitable substrates for supporting the formation of sensor array 106 sensors 202 include, without limitation, silicon substrates, gallium arsenide substrates, silica substrates, ceramic substrates, and glass substrates.

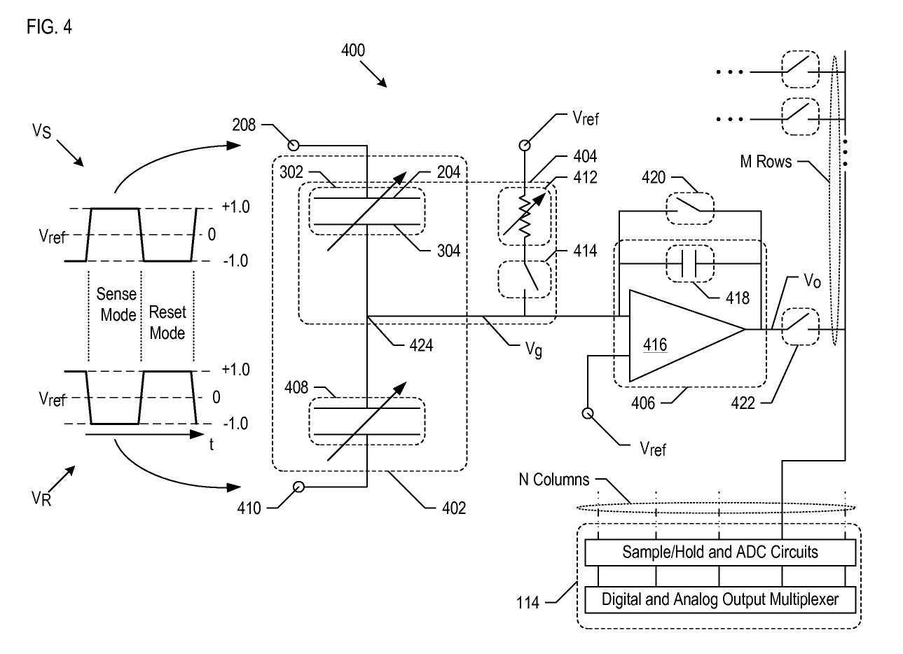

FIG. 4 depicts a schematic diagram of details of a portion of circuit for reading the output of a capacitive sensor, in accordance with the illustrative embodiment of the present invention. Circuit 400 comprises two capacitor bridge circuit 402, filter 404, and integrator circuit 406.

Two capacitor bridge circuit 402 comprises sense capacitor 302, reference capacitor 408, and voltage inputs 208 and 410. In some embodiments, reference capacitor 408 is a variable capacitor whose capacitance can be tuned. In some embodiments, reference capacitor 408 comprises a network of capacitors and switches. These switches enable each capacitor to be switched into or out of the network as desired, thereby controlling the composite capacitance value of reference capacitor 408. These capacitors are interconnected to each other and to the input voltages such that the value of each individual capacitor can either add or subtract from the composite capacitance value of reference capacitor 408. In some embodiments, the switches are 3-pole switches that enable each capacitor to be connected to V_{S}, V_{R}, or open circuited. Capacitors in the network that forms reference capacitor 408 include:
i. parallel plate capacitors; or
ii. CMOS capacitors; or
iii. MEMS capacitors; or
iv. MOS transistors having interconnected drain and source contacts; or
v. any combination of i, ii, iii, and iv.

In some embodiments, reference capacitor 408 is a fixed capacitor.

Filter 404 comprises voltage input V_{ref}, resistor 412 with a value R, filter switch 414, sense capacitor 302 with a nominal value C_{S}, and reference capacitor with a value C_{R}. When filter switch 414 is closed, filter 404 is formed by resistor 412 and sense capacitor 302 with a time constant, τ, which is approximated by the relationship τ=R(C_{S}+C_{R}). Filter 404 provides a sink for kinetic energy in sensor 202, which manifests itself as mechanical motion of plate 204. For sensor structures with high mechanical quality factors (Q>1000), significant resonant motion of plate 204 (i.e., vibration) does not occur at frequencies much below the resonance frequency of the sensor structure. The resonant frequency of the sensor structure is a function of the mechanical stiffness of support arm 206 and the mass of plate 204. At vibration frequencies above the resonant frequency of sensor 202, the motion of the cantilever plate 204 generates a voltage that alternates around the reference voltage V_{ref}. This creates an alternating voltage across the resistor 412 and a resultant alternating current through resistor 412. The current in resistor 412 heats the resistor, thereby dissipating the electrical energy and the mechanical energy in sensor 202. Mechanical motion of plate 204 occurs when the electric field applied to sense capacitor 302 changes at a rate at which plate 204 can physically respond, for example, during initial sensor turn-on or during slow transitions of the bias voltages V_{S} and V_{R} from high to low bias and vice versa. It will be appreciated by one of ordinary skill in the art that the precise value of τ is affected by such factors as applied voltage, the area of plate 204, initial spacing between the capacitor plates 204 and 304, and the resonant frequency and other mechanical properties of sensor 202.

In the illustrative embodiment, V_{ref} is ground potential (i.e., zero volts), although it will be clear to those of ordinary skill in the art, after reading this specification, how to make and use alternative embodiments of the present invention wherein V_{ref} is a voltage other than ground. In some alternative embodiments, for example, V_{ref} is set to a voltage substantially halfway between ground potential and a supply rail voltage.

In the illustrative embodiment, both sense capacitor 302 and reference capacitor 408 have a value of approximately 20 femtofarads (fF). In addition, sensor 202 has a mechanical resonant frequency of approximately 15 kHz, which dictates that environmentally-induced motion of plate 302 will be limited to approximately 15 kHz as well. The cutoff frequency of filter 404, therefore, is selected to by approximately 15 kHz. As a result a value of 100 GΩ is selected for resistor 412. In some embodiments, the value of resistor 412 is empirically chosen to achieve a desired performance level for filter 404. In these embodiments, the value of resistor 412 may deviate by as much as two orders of magnitude from the value approximated by the formula f=2π/R(C_{S}+C_{R}).

In some embodiments, sense capacitor 302 has a capacitance within the range of 1 fF to 30 fF. In some embodiments, the microcantilever sensor structure 202 is fabricated such that its mechanical resonant frequency is within the range of 5 kHz to 50 kHz, and the resulting environmentally-induced motion of plate 302 will be limited to frequencies within the range of 5 kHz to 50 kHz. In some embodiments, therefore, the cut-off frequency of filter 404, f=2π/R(C_{S}+C_{R}) will be selected as a frequency of approximately 5 kHz to 50 KHz. As a result, in many embodiments the value of resistor 412 is selected to be within the range of 100 MΩ to 100 GΩ.

Integrator circuit 406 receives signal V_{g} from two capacitor bridge circuit 402 and provides output signal Vₒ. In some embodiments, signal Vₒ is provided to additional circuitry that comprises a high-impedance input. Integrator circuit 406 comprises amplifier 416 and capacitor 418. In some embodiments, integrator circuit 406 provides:
i. gain; or
ii. voltage integration; or
iii. signal conditioning; or
iv. any combination of i, ii, and iii.

It should be noted that integrator circuit 406 is just one example of an integrator circuit that can be used in circuit 400. It will be clear to those skilled in the art how to specify, make, and use integrator circuit 406.

Integrator reset switch 420 provides a means of “shorting out” integrator circuit 406, during the reset mode of operation. Typically, integrator reset switch 420 is open during the sense mode of operation of circuit 400 and closed during the reset mode after the charge on the integration capacitor 418 has been read by the readout circuit sample and hold circuits.

In operation, circuit 400 provides 1) a means of providing a signal (i.e., V_{g}) that is a function of the intensity of electromagnetic radiation incident on plate 204; 2) a means of removing mechanical noise associated with the motion of plate 204; and 3) an output signal (i.e., Vₒ) of sufficient magnitude to be useful to additional circuitry.

Although in the illustrative embodiment of the present invention two capacitor bridge circuit 402 comprises a sense capacitor whose capacitance is a function of the intensity of incident electromagnetic radiation, it will be clear to those of ordinary skill in the art, after reading this specification, how to make and use alternative embodiments of the present invention wherein two capacitor bridge circuit 402 comprises a sense capacitor whose capacitance varies in response to any environmental stimulus.

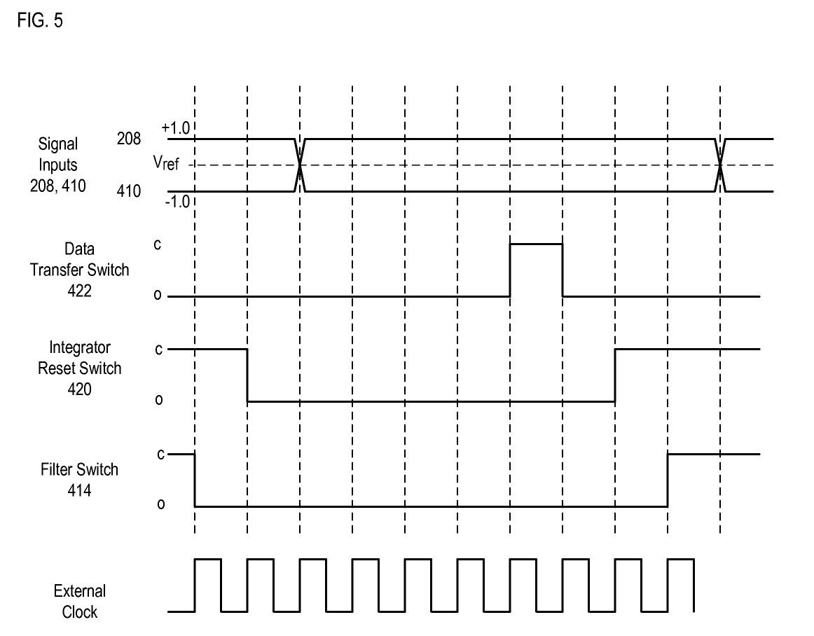

FIG. 5 depicts a timing diagram of signal levels within circuit 400.

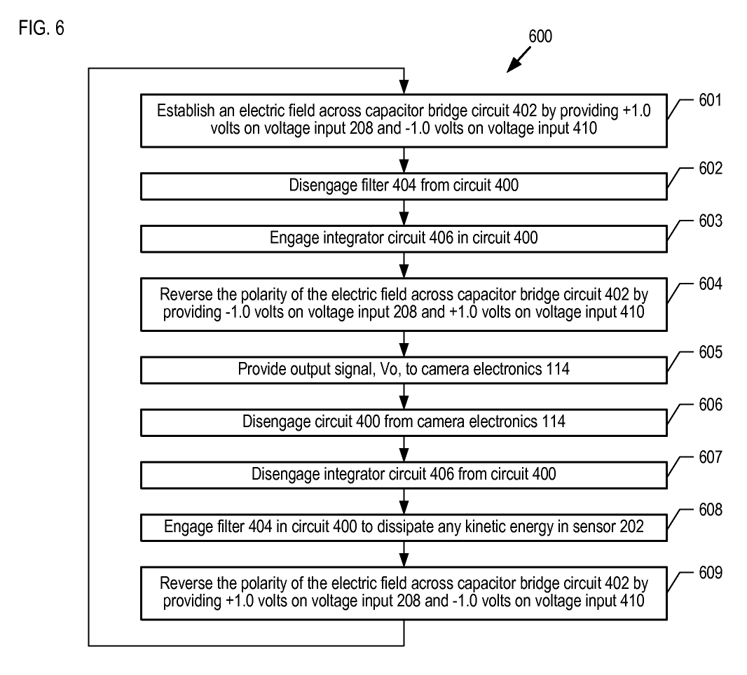

FIG. 6 depicts a method for operating circuit 400.

Referring now to FIGS. 5 and 6 and with continuing reference to FIG. 4, signal timing diagram 500 of circuit 400 is described in conjunction with method 600, which describes operations suitable for operating circuit 400. Method 600 describes operations suitable for interrogating one electromagnetic radiation sensor in a two-dimensional array of such sensors. It will be clear to those skilled in the art, after reading this specification, how to apply row and column addressing algorithms and methods appropriately in order to read each sensor in an M row×N column array of sensors in accordance with the present invention.

Method 600 begins with operation 601, wherein input signal V_{S} is applied to voltage input 208 and input signal V_{R} is applied to voltage input 410. During the sense mode, the voltage level of input signal V_{S} is equal to +1.0 volts and the voltage level of input signal V_{R} is equal to −1.0 volts. As a result, an electric field is developed across sense capacitor 302 in the direction from plate 204 to substrate electrode 304. The magnitude of this electric field is a function of the geometry of sense capacitor 302 and the relative voltage drop across sense capacitor 302 and reference capacitor 408 (i.e., their relative capacitance values). As a result of the applied electric field, charge builds up on plate 204 and electrode 304. As discussed above and with reference to FIGS. 3A and 3B, the capacitance of sense capacitor 302 is a function of the intensity of electromagnetic radiation incident upon plate 204. In some embodiments, input signals V_{S} and V_{R} are applied with a slew rate less than the resonant frequency of the mechanical resonance of sensor 202. Since sensor 202 typically exhibits a high mechanical Q (i.e., Q>1000), “turning on” sensor 202 at a rate slower than the mechanical resonance imparts little or no mechanical energy to the sensor.

Although in the illustrative embodiment input signals V_{S} and V_{R} have voltage levels equal to ±1.0 volts, it will be clear to those skilled in the art, after reading this specification, how to make and use alternative embodiments of the present invention wherein input signals V_{S} and V_{R} have other voltage levels. The choice of voltage level for the input signals is dependent upon the electronics used in circuit 400, as well as the mechanical design of sensor 202.

It will be noted by those of ordinary skill in the art that when an electric field is developed across plate 204 and substrate electrode 304, an electrostatic force is developed between these capacitor plates. This electrostatic force, if large enough, will cause plate 204 to move toward substrate electrode 304, thereby influencing the output signal of sensor 202. The voltage levels for input signals V_{S} and V_{R}, therefore, are typically selected to avoid inducing sufficient electrostatic force to displace plate 204 from its position due to absorbed electromagnetic radiation. In some alternative embodiments, however, a voltage level for input signals V_{S} and V_{R} is selected wherein some displacement of plate 204 is induced. In some embodiments wherein some displacement of plate 204 is induced by input signals V_{S} and V_{R}, reference capacitor 408 is adjusted to compensate for the induced change in the capacitance of sense capacitor 302.

In the absence of electromagnetic radiation, the capacitance values of sense capacitor 302 and reference capacitor 408 are substantially equal. As a result, the voltage differential between voltage inputs 208 and 410 is split evenly between the two capacitors and the voltage at common node 424, located between the capacitors (i.e., V_{g}), is substantially equal to zero. In some embodiments, in the absence of electromagnetic radiation, the capacitance values of sense capacitor 302 and reference capacitor 408 are substantially equal after the application of input signals V_{S} and V_{R}.

In some embodiments, operation 601 is performed while sensor 202 is not exposed to electromagnetic radiation. In some embodiments, a calibration is done to null out any voltage offset on V_{g} in the absence of incident radiation.

When plate 204 absorbs electromagnetic radiation, however, the spacing, s, between plate 204 and substrate electrode 304 changes. As a result, the capacitance of sense capacitor 302 changes and V_{g} develops a non-zero value.

At operation 602, filter 404 is disengaged from circuit 400 by the opening of filter switch 414.

At operation 603, integrator reset switch 420 is opened to engage integrator circuit 406 in circuit 400.

At operation 604, the polarity of applied input signals V_{S} and V_{R} is reversed. In other words, −1.0 volts is applied to signal input 208 and +1.0 volts is applied to signal input 410. As a result of operation 604, the polarity of the electric field across sense capacitor 302 is reversed. The magnitude of this electric field, however, remains the same since the magnitude of the voltage differential applied to voltage inputs 208 and 410 remains the same. Since the magnitude of the electric field remains constant, no change in the electrostatic force between plate 204 and substrate electrode 304 is induced.

When the polarity of the voltages applied to signal inputs 208 and 410 is reversed, a flow of charge is induced in two capacitor bridge circuit 402. This flow of charge is sensed by integrator circuit 416 and stored on integration capacitor 418. As a result, voltage V₀ is generated at the output of integrator circuit 406.

At operation 605, data transfer switch 422 is closed to enable integrator circuit 406 to provide output signal V₀ to camera electronics 114.

At operation 606, data transfer switch 422 is opened to disengage circuit 400 from camera electronics 114.

At operation 607, integrator reset switch 420 is closed. As a result, integration capacitor 418 is discharged and integrator circuit 406 is reset in preparation for the next sense mode.

At operation 608, filter switch 414 is closed to engage filter 404 in circuit 400, which dissipates some or all of any kinetic energy developed in sensor 202. In some embodiments, filter 402 is not engaged at operation 608.

At operation 609, the polarity of input signals V_{S} and V_{R} is reversed. In other words, a voltage of +1.0 volts is applied to voltage input 208, while a voltage of −1.0 volts is applied to voltage input 410. As a result, the polarity of the electric field across sense capacitor 302 is reversed. The magnitude of this electric field, however, remains the same since the magnitude of the voltage differential applied to voltage inputs 208 and 410 remains the same as it was during the sense mode. Since the magnitude of the electric field remains constant, no change in the electrostatic force between plate 204 and substrate electrode 304 is induced. After operation 609, circuit 400 can once again be put into sense mode by opening switches 420 and 414.

It should be noted that the instantaneous magnitude of the electric field between plate 204 and substrate electrode 304 is different during the time when the polarity of input signals V_{S} and V_{R} is being switched. In order to avoid significant mechanical response of sensor 202 during these transitional periods, the electrical slew rate of the voltage signals is kept well above the resonant period of sensor 202 (i.e., 1/ωᵣₑₛ, wherein ωᵣₑₛ is the mechanical resonant frequency of sensor 202). For many typical sensor structures, a voltage rise time of less than 10 nanoseconds is suitable, although the suitability of a voltage rise time is dependent upon the mechanical characteristics of any specific sensor structure.

In some embodiments of the present invention, the voltage bias across the capacitive sensing element is switched in polarity many times within a single sense period in order to improve the mechanical noise performance of the sensor system. In these embodiments, however, the magnitude of the electric field developed across the plates of the capacitive sensing element remains substantially constant. In some embodiments additional signal integration circuitry receives the output of integrator circuit 406 in order to further improve the quality of output signal Vₒ.

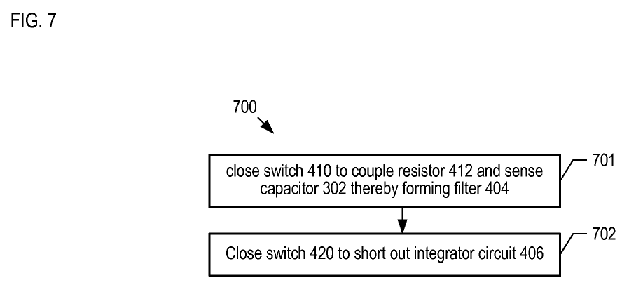

FIG. 7 depicts a method for dissipating kinetic energy in sensor 202. As described above, and with reference to FIG. 4, kinetic energy in sensor 202 that has a frequency above the cut-off frequency of filter 404 is dissipated through resistive heating of resistor 412 in filter 404. Method 700 is used to dissipate kinetic energy that arises as mechanical resonance due to voltage changes at sensor turn-on or during transitions between the sense and reset modes.

Method 700 begins with operation 701, wherein switch 414 is closed to couple resistor 412 to sense capacitor 302 and form a hi-pass filter.

At operation 702, switch 420 is closed to shunt integrator circuit 406. In some embodiments, operation 702 couples the input node of filter 404 (i.e., common node 424 of capacitive bridge circuit 402) to a high impedance input stage which is part of the circuitry to which circuit 400 is connected. As a result, current due to kinetic energy in sensor 202 is forced through resistor 412 where it dissipates as resistive heating. It should be noted that the amount of heat generated by dissipation of this current is typically very low so that it does not affect the output signal of sensor 202.

It is to be understood that the disclosure teaches just one example of the illustrative embodiment and that many variations of the invention can easily be devised by those skilled in the art after reading this disclosure and that the scope of the present invention is to be determined by the following claims.

What is claimed is:

1. A circuit comprising:
(1) a two capacitor bridge circuit comprising;
(a) a sense capacitor having a first terminal and a second terminal, wherein the capacitance of said sense capacitor is a function of an environmental stimulus; and
(b) a reference capacitor having a first terminal and a second terminal, wherein said second terminal of said reference capacitor and said second terminal of said sense capacitor are electrically-connected;
(2) a first input for providing a first voltage signal, wherein said first input and said first terminal of said sense capacitor are electrically-connected; and
(3) a second input for providing a second voltage signal, wherein said second input and said first terminal of said reference capacitor are electrically-connected;
wherein said first voltage signal and said second voltage signal produce a first electric field across said two capacitor bridge circuit during a sense mode and a second electric field across said two capacitor bridge circuit during a reset mode, and wherein said first electric field and said second electric field have substantially equal magnitude and opposite polarity.

2. The circuit of claim 1:
wherein said first voltage signal comprises a first voltage during said sense mode and a second voltage during said reset mode, wherein said first voltage and said second voltage are referenced to a reference voltage;
wherein said second voltage signal comprises a third voltage during said sense mode and a fourth voltage during said reset mode, wherein said third voltage and said fourth voltage are referenced to said reference voltage;
wherein said first voltage and said third voltage have substantially equal magnitude and opposite polarity;
wherein said second voltage and said fourth voltage have substantially equal magnitude and opposite polarity; and
wherein said first voltage and said second voltage have substantially equal magnitude and opposite polarity.

3. The circuit of claim 2 wherein said reference voltage is substantially equal to ground potential.

4. The circuit of claim 2 wherein said first voltage and said fourth voltage are substantially equal to a supply voltage, and wherein said second voltage and said third voltage are substantially equal to ground potential, and further wherein said reference voltage is substantially equal to one half of said supply voltage.

5. The circuit of claim 1 further comprising a reference voltage input and a damping circuit having a first terminal and a second terminal, wherein said reference voltage input and said first terminal of said damping circuit are electrically-connected, and wherein said second terminal of said damping circuit and said second terminal of said sense capacitor are electrically-connected.

6. The circuit of claim 5 wherein said damping circuit comprises a resistor and a switch, and further wherein said resistor and said switch are electrically-connected.

7. The circuit of claim 1 wherein said sense capacitor comprises a first capacitor plate that is suspended above a second capacitor plate by a support arm, and wherein the spacing between said first capacitor plate and said second capacitor plate is a function of the intensity of electromagnetic radiation that is incident on said first capacitor plate.

8. A method comprising:
establishing a first electric field across a two capacitor bridge circuit during a sense mode, wherein said two capacitor bridge circuit comprises a sense capacitor and a reference capacitor, and wherein the capacitance of said sense capacitor is a function of an environmental stimulus; and
establishing a second electric field across said two capacitor bridge circuit during a reset mode;
wherein said first electric field and said second electric field have substantially equal magnitude and opposite polarity.

9. The method of claim 8 wherein said first electric field is established by providing a first voltage on a first input node of said two capacitor bridge circuit and a second voltage on a second input node of said two capacitor bridge circuit, and wherein said first voltage and said second voltage are each referenced to a reference voltage, and further wherein said first voltage and said second voltage have substantially equal magnitude and opposite polarity.

10. The method of claim 9 wherein said second electric field is established by providing a third voltage on said first input node and a fourth voltage on said second input node, and wherein said third voltage and said fourth voltage are referenced to said reference voltage, and further wherein said third voltage is substantially equal to said second voltage and said fourth voltage is substantially equal to said first voltage.

11. The method of claim 8 further comprising:
converting mechanical energy in said sense capacitor into an electric current; and
injecting said electric current into a filter comprising said reference capacitor and a resistor.

12. The method of claim 8 further comprising forming said sense capacitor, wherein said sense capacitor comprises a first capacitor plate supported above a second capacitor plate by a support arm, and wherein the spacing between said first capacitor plate and said second capacitor plate is a function of said environmental stimulus.

13. The method of claim 12 wherein said environmental stimulus comprises electromagnetic radiation that is incident on said first capacitor plate.

14. The method of claim 8 wherein said environmental stimulus comprises electromagnetic radiation that is incident on said sense capacitor.

15. The method of claim 14 wherein said electromagnetic radiation is characterized by a wavelength within the range of 1 nanometer to 100 microns.

16. A method comprising:
converting mechanical energy in a sense capacitor into an electric current, wherein the capacitance of said sense capacitor is a function of mechanical response of said sense capacitor to an environmental stimulus;
injecting at least a portion of said electric current into a resistor, wherein said resistor has a value within the range of 1 MΩ to 100 GΩ; and
dissipating said electric current in said resistor through resistive heating.

17. The method of claim 16 wherein said portion of electric current is injected into a resistor having a value within the range of 300 MΩ to 3 GΩ.

18. The method of claim 16 further comprising establishing a first electric field across a two capacitor bridge circuit, wherein said two capacitor bridge circuit comprises said sense capacitor and a reference capacitor, and wherein said first electric field is established across said two capacitor bridge circuit during a sense mode, and further wherein said first electric field has a first magnitude and a first polarity.

19. The method of claim 18 wherein said first electric field is established by applying a first voltage to a first signal input of said two capacitor bridge circuit and a second voltage to a second signal input of said two capacitor bridge circuit, and wherein said first voltage has a first rise time and said second voltage has a second rise time, and further wherein each of said first rise time and said second rise time are less than a mechanical resonance period of said sense capacitor.

20. The method of claim 18 further comprises establishing a second electric field across said two capacitor bridge circuit during a reset mode, wherein said second electric field is established across said two capacitor bridge circuit during a reset mode, and wherein said second electric field has a second magnitude and a second polarity, and wherein said first magnitude and said second magnitude are substantially equal, and further wherein said first polarity and said second polarity are opposite polarities.

21. The method of claim 16 further comprising forming said sense capacitor, wherein said sense capacitor comprises a first capacitor plate supported above a second capacitor plate by a support arm, and wherein the spacing between said first capacitor plate and said second capacitor plate is a function of said environmental stimulus.

22. The method of claim 21 wherein said environmental stimulus comprises electromagnetic radiation that is incident on said first plate.

23. The method of claim 16 wherein said environmental stimulus comprises electromagnetic radiation that is incident on said sense capacitor.
